(19) United States
(12) Patent Application Publication
(10) Pub. No.: US 2026/0236555 A1
(43) Pub. Date: Aug. 13, 2026

(54) VECTOR PROCESSING FOR IN-MEMORY COMPUTING

(71) Applicant: AXELERA AI BV, Eindhoven (NL)

(72) Inventors: Evangelos Eleftheriou, Rüschlikon (CH); Michael Platzer, Wien (AT); Florian Zaruba, Zürich (CH); Domenic Wüthrich, Winterthur (CH)

(21) Appl. No.: 19/160,708

(22) PCT Filed: Mar. 7, 2023
(86) PCT No.: PCT/EP2023/055771

§ 371 Date: Aug. 28, 2025

(51) Int. Cl. G06F 17/16

(52) U.S. Cl. CPC G06F 17/16

(57) ABSTRACT

The invention is notably directed to an information-processing apparatus (10), which basically includes a vector processing unit (VPU) and an in-memory compute unit (IMC unit). The VPU (14) has vector registers designed to store vector components. The IMC unit (15) has a crossbar array structure, which is adapted to store values (called weights). The IMC unit is connected to the vector registers (148) of the VPU. The information-processing apparatus is configured to perform several operations, including vector transit operations, vector feed operations, and vector readout operations. In operation, the vector transit operations cause to store vector components of input vectors in the vector registers of the VPU. Such components are typically fetched from a neighbouring memory (11), upon on receiving corresponding instructions from a main processing unit (12), to which the VPU is connected. The vector feed operations feed the input vector components as input to the IMC unit, from the vector registers. This, in turn, causes the IMC unit to perform matrix-vector multiplications based on the weights and the input vector components, to accordingly obtain output vectors. Finally, the vector read-out operations write output vector components of the output vectors in the vector registers. From this point on, the output vector components can be transferred to the memory or the main processing unit (for further processing), or further processed in the VPU, prior to being transferred to the memory or the main processing unit. The invention is further directed to related systems and methods.

### RELATED APPLICATION(S)

This application claims the benefit of internal application PCT/EP2023/055771 filed on Mar. 7, 2023. The entirety of the foregoing application is incorporated by reference herein.

### TECHNICAL FIELD

The invention relates in general to the field of hardware-accelerated information processing, particularly in-memory computing, and vector processing. In particular, the invention is directed to methods and systems relying on an in-memory compute unit having a crossbar array structure for efficiently performing matrix-vector multiplications, where the in-memory compute unit is connected to a vector processing unit to exploit vector registers of the vector processing unit as memory buffers.

### BACKGROUND

Artificial neural networks (ANNs) such as deep neural networks (DNNs) have revolutionized the field of machine learning by providing unprecedented performance in solving cognitive data-analysis tasks. ANN operations mostly involve matrix-vector multiplications (MVMs), which account for 70 to 90% of the total neural network operations, irrespective of the ANN architecture. MVM operations pose multiple challenges, because of their recurrence, universality, compute, and memory requirements. Traditional computer architectures are based on the von Neumann computing concept, according to which processing capability and data storage are split into separate physical units. Such architectures suffer from congestion and high-power consumption, as data must be continuously transferred from the memory units to the control and arithmetic units through interfaces that are physically constrained and costly.

One possibility to accelerate MVMs is to use dedicated hardware acceleration devices, such as dedicated circuits having a crossbar array structure. This type of circuit includes input lines and output lines, which are interconnected at cross-points defining cells. The cells contain respective memory devices (or sets of memory devices), which are designed to store respective matrix coefficients. Vectors are encoded as signals applied to the input lines of the crossbar array to perform the MVMs by way of multiply-accumulate (MAC) operations. Such an architecture can map MVMs simply and efficiently. The weights are updated (i.e., replaced) by reprogramming the memory elements, to perform successive matrix-vector multiplications. Such an approach breaks the “memory wall” as it fuses the arithmetic-and memory unit into a single in-memory-computing (IMC) unit, whereby processing is done much more efficiently in or near the memory (i.e., the crossbar array). Plus, an IMC unit provides a solution to the Von-Neumann Bottleneck on the instruction interface as a single instruction may suffice to operate the MVM over multiple cycles.

While the main computational load of ANNs such as DNNs revolves around MAC operations, their execution involves additional operations for the IMC unit to communicate with external computerized entities, which slow down the execution of the MVMs. Therefore, the present inventors took up the challenge to further accelerate IMC computations.

### SUMMARY

According to a first aspect, the present invention is embodied as an information-processing apparatus, which basically includes a vector processing unit (VPU) and an in-memory compute unit (IMC unit). The VPU has vector registers designed to store vector components. The IMC unit has a crossbar array structure, which is adapted to store values (called weights). The IMC unit is connected to the vector registers of the VPU. The information-processing apparatus is configured to perform several operations, including vector transit operations, vector feed operations, and vector readout operations. In operation of the apparatus, the vector transit operations cause to store vector components of input vectors in the vector registers of the VPU. Such components are typically fetched by the VPU from a neighbouring memory, upon receiving corresponding instructions from a main processing unit. The vector feed operations cause to feed the input vector components (as input) to the IMC unit, from the vector registers. This, in turn, causes the IMC unit to perform matrix-vector multiplications (MVMs) based on the weights and the input vector components to accordingly obtain output vectors. Finally, the vector readout operations write output vector components of the output vectors in the vector registers. From this point on, the output vector components can for instance be transferred to the memory or the main processing unit (for further processing), or further processed in the VPU, prior to being transferred to the memory or the main processing unit.

According to the proposed solution, the vector registers of the VPU are used both as source and destination buffers, whereby vector components can efficiently be injected to and received from the IMC unit. That is, the pipeline parallelism enabled by the vector registers makes it possible to operate the IMC unit more efficiently for it to perform MVMs, let alone the MVM acceleration that is inherently achieved through the IMC unit itself. Besides, one may take advantage of the vector processing capability of the VPU to efficiently perform operations on the vector components that are temporarily stored in the registers, as in embodiments.

In some scenarios, there is little advantage to directly load a weight matrix from a neighbouring memory into the IMC unit compared to loading weights into the vector registers first. In such situations, the vector registers can be leveraged to store and change the weights, which makes it possible to simplify the cell programming. Thus, in embodiments, the information-processing apparatus is further configured to perform weight transit operations to store the weights in the vector registers and weight feed operations to feed the weights to the IMC unit from the vector registers, so as to store the weights across the crossbar array structure. The apparatus is preferably configured to perform the weight transit operations and the weight feed operations step wise, in accordance with a memory capacity of the vector registers and/or throughput capabilities of the vector registers.

Preferably, the crossbar array structure includes N×M cells comprising respective memory systems, each designed to store K weights, where K≥2, whereby the crossbar array structure includes N×M memory systems adapted to store K sets of N×M weights, instead of a single set of N×M weights (as in less preferred variants). In addition, the crossbar array structure includes a selection circuit, which is configured to enable N×M weights as active weights by selecting, for each of the memory systems, a weight from its K weights and setting the selected weight as an active weight. The aim is to reduce idle times of the crossbar array structure (i.e., the core compute device), something that is achieved by switching between active weights locally to accordingly reduce the frequency of data exchanges with an external memory unit. Note, the selection may possibly allow an entire matrix of N×M weights to be selected at a time.

What is more, the weights can be proactively loaded (i.e., prefetched during the compute cycles) to further reduce idle times of the crossbar structure. That is, in preferred embodiments, the information-processing apparatus is further configured to prefetch q sets of N×M weights while the IMC unit performs MVMs based on the N×M weights that are currently active, so as to store the prefetched weights in the N×M memory systems, in place of q sets of N×M weights that are currently not enabled as active weights, where 1≤q≤K−1.

Preferably, the selection circuit includes N×M multiplexers, each connected to each of the K memory elements of a respective one of the N×M memory systems, as well as selection control lines, which are connected to each of the multiplexers, so as to allow any one of the K weights of each of the memory systems to be selected and set as an active weight, in operation.

In embodiments, the vector processing unit further comprises an accumulation circuit interfaced with the vector registers. The accumulation circuit may for instance form part of, or be connected with, a component of the vector processing unit, such as a vector execution unit. The accumulation circuit is configured to accumulate output vector components of output vectors obtained from the IMC unit. This way, output vector components of output vectors are accumulated in the vector registers. This, in operation, makes it possible to accumulate outcomes of matrix-vector multiplications based on very large operands, where such operands are mapped onto the inputs to and/or weights of the IMC unit. In variants, a similar accumulation circuit may be implemented in the IMC unit. Preferred, however, is to leverage the processing capability of the vector processing unit to perform accumulations directly in the vector registers, rather than through an accumulation circuit provided in the IMC unit.

The vector registers are designed to store a given number of numerical values. Preferably, said given number is larger than or equal to a smallest value of N and M. This way, the weight values stored in the IMC unit can be updated at least column-by-column or row-by-row. Note, in the present context, updating the weights means replacing at least some of the weight values stored in the IMC unit by new weight values, with a view to performing further MVMs based on new weight values. This kind of updates is unrelated to weight updates as occurring during the training of the underlying computational model, if any.

In preferred embodiments, the information-processing apparatus further includes a controller, which preferably forms part of the IMC unit, or is closely interfaced therewith. Moreover, the VPU includes a vector instruction decoder connected to said controller, the vector instruction decoder is configured to decode vector instructions and transmit the decoded vector instructions to the controller. The controller is further configured to orchestrate the vector feed operations, the MVMs, and the vector readout operations, based on the decoded vector instructions transmitted from the vector instruction decoder.

As said, the information-processing apparatus can be configured to store the weights across the crossbar array structure. The vector instructions may form part of a vector instruction set designed in accordance with a base instruction set architecture. Now, the latter can advantageously be augmented with two types of vector instructions, respectively designed to cause to store the weights and perform the MVMs, in operation of the apparatus.

In embodiments, the information-processing apparatus further comprises a main processing unit configured to execute non-vector instructions. The main processing unit is interfaced with the VPU to forward the vector instructions to the vector instruction decoder.

In preferred embodiments, the information-processing apparatus further comprises a memory interfaced with each of the main processing unit and the VPU. The main processing unit further comprises an instruction decoder configured to fetch instructions from the memory, decode the fetched instructions, and accordingly forward the vector instructions to the VPU. The latter further comprises a vector load and store unit configured to perform the vector transit operations and the vector readout operations (as well as weight transit operations, if any), by transferring corresponding values between the memory and the vector registers, in operation. The IMC unit is preferably integrated in the VPU. Alternatively, the IMC unit may be co-integrated with the VPU in the information-processing apparatus.

The invention may also be embodied as an information-processing system, which comprises one or more information-processing apparatuses as described above.

According to another aspect, the invention is embodied as a method of operating an IMC unit to perform MVMs. As explained above, the IMC unit has a crossbar array structure storing weights; the IMC unit is connected to vector registers of a VPU. The method first comprises performing a vector transit operation to store input vector components of an input vector in the vector registers. Next, a vector feed operation is performed to feed the input vector components as input to the IMC unit, from the vector registers. Then, the method operates the IMC unit to perform an MVM based on the weights stored and the input vector components fed to the IMC unit, to obtain an output vector. Finally, a vector readout operation is performed to write output vector components of the output vector in the vector registers. Such steps are typically repeatedly performed, to successively perform MVMs.

Preferably, the method further comprises, prior to performing the vector transit operation and the vector feed operation, performing weight transit operations to store the weights in the vector registers and weight feed operations to feed the weights to the IMC unit, so as to store the weights across the crossbar array structure. The weights may possibly be fetched directly from the memory. In variants, the weights transit through the vector registers.

In preferred embodiments, the crossbar array structure includes N×M cells comprising respective memory systems, each designed to store K weights, K≥2, whereby the crossbar array structure includes N×M memory systems adapted to store K sets of N×M weights. In that case, the method may further comprise, prior to performing the MVM, enabling the N×M weights as active weights by selecting, for each of the memory systems, a weight from its K weights and setting the selected weight as an active weight. The weight transit operations and the weight feed operations are performed to store the K sets of N×M weights across the N x M memory systems of the crossbar array structure. Note, the weight transit operations and the weight feed operations may possibly have to be performed step wise, this depending on a memory capacity of the vector registers.

Such an architecture allows the weights to be proactively fetched. That is, in preferred embodiments, the method further comprises prefetching q sets of N×M weights while the IMC unit performs MVMs based on the currently active weights, to store the prefetched weights in the N×M memory systems, in place of q sets of N×M weights that are currently not enabled as active weights, where 1≤q≤K−1.

In embodiments, the method further comprises, at the VPU, decoding vector instructions and executing the decoded instructions to orchestrate the weight transit operations, the weight feed operations, the vector transit operations, the vector feed operations, and the vector readout operations. As said, the vector instructions may form part of a vector instruction set designed in accordance with a basis instruction set architecture, which is augmented with two types of vector instructions. The latter are designed to respectively cause to perform the weight feed operations and the MVMs. In preferred embodiments, the method further comprises sending the vector instructions from a main processing unit interfaced with the VPU, prior to decoding the vector instructions at the VPU. The input vector components are preferably fetched from a memory interfaced with the VPU, prior to performing the vector transit operation, so as to store the input vector components of this input vector in the vector registers. Similarly, the output vector components can be transferred from the vector registers to the memory, after performing the vector readout operation.

### BRIEF DESCRIPTION OF THE DRAWINGS

These and other objects, features and advantages of the present invention will become apparent from the following detailed description of illustrative embodiments thereof, which is to be read in connection with the accompanying drawings. The illustrations are for clarity in facilitating one skilled in the art in understanding the invention in conjunction with the detailed description.

In the drawings:

FIG. 1 is a diagram schematically illustrating selected components of an information-processing apparatus, which includes a vector processing unit connected to an in-memory compute (IMC) unit, according to embodiments;

FIG. 2A schematically depicts the crossbar array structure of the IMC unit of FIG. 1, as in embodiments. FIG. 2B schematically illustrates the integration of the IMC unit in an apparatus as in FIG. 1;

FIG. 3 is a diagram of an IMC unit involving columns of arithmetic units (multipliers and adder trees) connected to respective columns of memory elements. Each cell includes a memory system of several memory elements, as in embodiments. Overall, crossbar array structure of the IMC unit includes N×M memory systems capable of storing K sets of N×M weights;

FIG. 4 schematically depicts a given row of memory cells, as well as portions of a programming circuit and a selection circuit, as in embodiments. The depicted portions of the programming circuit and the selection circuit are connected to a single memory cell. Other portions of such circuits are not shown, for the sake of depiction. In practice, however, the programming circuit and the selection circuit are typically connected to each memory cell;

FIG. 5 is a simplified circuit schematics of components of a selection circuit, which are connected to a respective memory cell, as in embodiments;

FIG. 6 schematically represents a computerized system involving several apparatuses according to embodiments of the invention. The system allows a user to interact with a server, in order to accelerate computation tasks that are offloaded to the apparatuses, as in embodiments; and

FIG. 7 is a flowchart illustrating high-level steps of a method of operating an IMC unit such as depicted in FIGS. 2A-3 to perform matrix-vector multiplications, according to embodiments.

The accompanying drawings show simplified representations of devices or parts thereof, as involved in embodiments. Similar or functionally similar elements in the figures have been allocated the same numeral references, unless otherwise indicated.

Apparatuses, systems, and methods embodying the present invention will now be described, by way of non-limiting examples.

### DETAILED DESCRIPTION OF EMBODIMENTS OF THE INVENTION

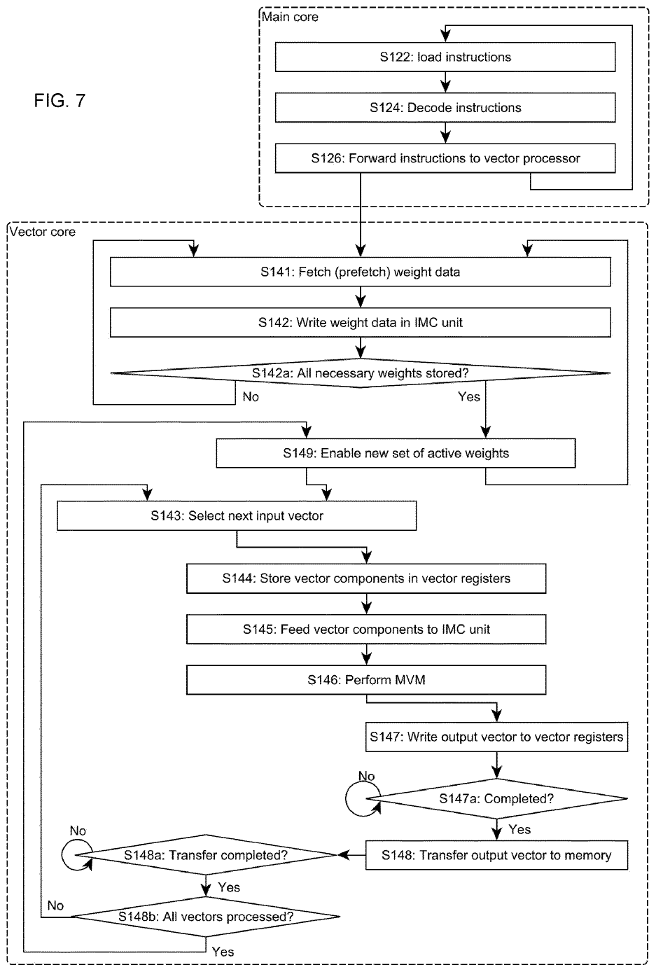

The following description is structured as follows. General embodiments and high-level variants are described in section 1, while section 2 addresses particularly preferred embodiments and technical implementation details. Note, the present method and its variants are collectively referred to as the “present methods”. All references Sn refer to methods steps of the flowcharts of FIG. 7, while numeral references pertain to devices, components, and other concepts, as involved in embodiments of the invention.

### 1. General Embodiments and High-level Variants

### 1.1. Information-Processing Apparatus

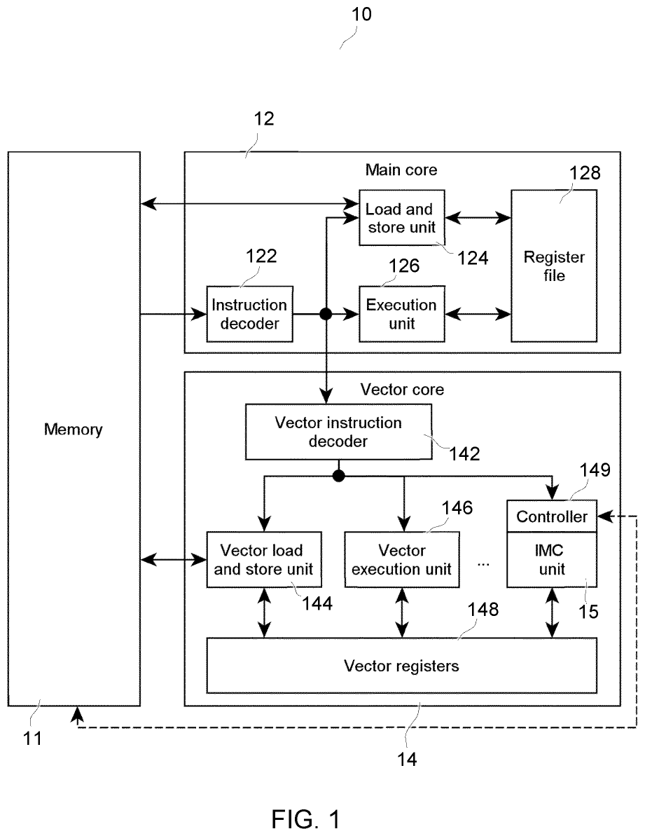

A first aspect of the invention is now described in reference to FIGS. 1-3. This aspect concerns an information-processing apparatus 10.

### 1.1.1. Main Features

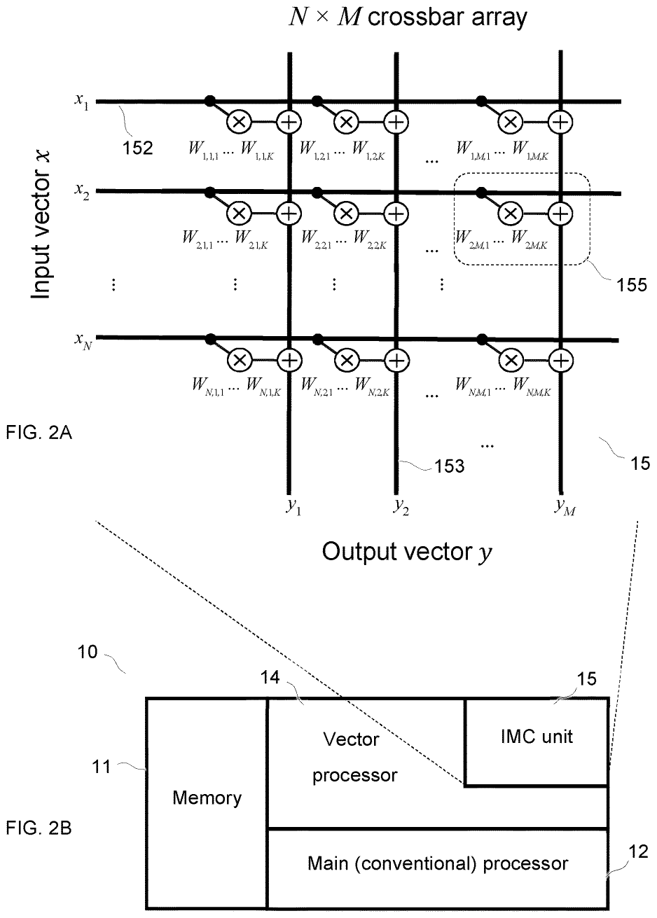

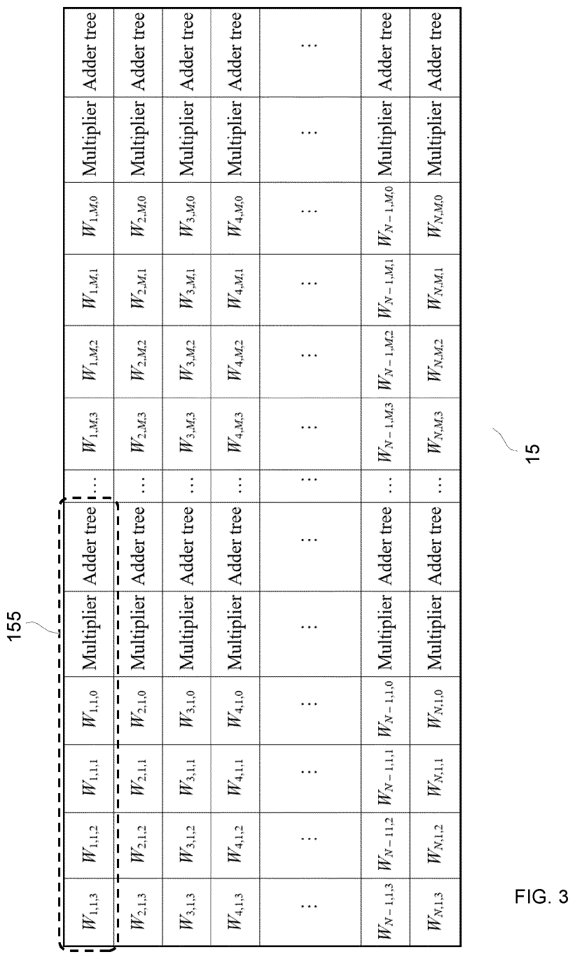

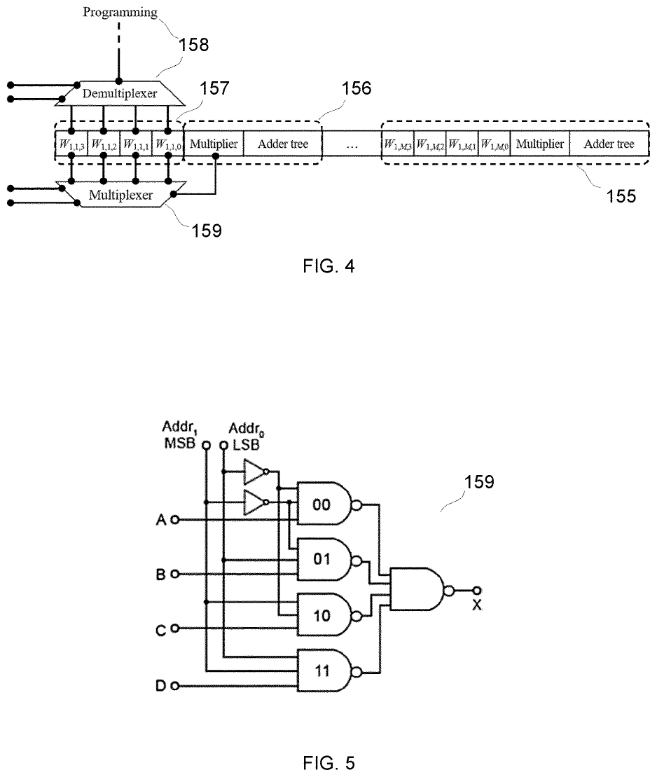

As seen in FIG. 1, the apparatus 10 basically includes a vector processing unit (VPU) 14 and an in-memory compute (IMC) unit 15. The VPU is a unit having vector processing capability. In particular, the VPU 14 includes vector registers 148, which together enable a vector register file. The vector registers 148 are designed to store vector components, i.e., arrays of numbers, meant to be vector processed. I.e., a VPU is a type of computer processor that operates on vectors of multiple elements instead of individual values. The IMC unit 15 includes a crossbar array structure, which is adapted to store weights, as illustrated in FIGS. 2 and 3. Like the IMC unit, the crossbar array structure is denoted by numeral reference 15 in the drawings. The crossbar array structure 15 shown in FIG. 2 includes N input lines 152 and M output lines 153, where N≥2 and M≥2, at the very least. In practice, the number of input lines 152 and output lines 153 will typically be on the order of several hundreds to thousands of lines. For example, arrays of 256×256, 512×512, or 1024×1024, may be contemplated, although N need not necessarily be equal to M. The input lines and output lines 152, 153 are interconnected at cross-points (i.e., junctions), which define N×M cells 155. The cells 155 include respective memory systems 157, see FIG. 4. Thus, the crossbar array structure 15 can store N×M weights. However, in preferred embodiments, the IMC unit is designed so as to be able to store K distinct sets of N×M weights, where K>1, for reasons explained later.

The IMC unit 15 is connected to the vector registers 148, to efficiently use the latter as memory buffers. That is, the information-processing apparatus 10 is configured to perform several operations, which make it possible to take advantage of the vector registers 148 to efficiently operate the IMC unit 15. Such operations essentially include vector transit operations, vector feed operations, and vector readout operations. In operation, the vector transit operations cause to store input vector components of input vectors in the vector registers 148. The vector feed operations cause to feed the input vector components (as input) to the IMC unit 15, from the vector registers. This, in turn, allows the IMC unit to perform matrix-vector multiplications (MVMs) based on the weights and the input vector components. Such operations cause the IMC unit to produce output vectors. Finally, vector readout operations are performed by the apparatus 10 to write output vector components of the output vectors in the vector registers 148.

By design, the IMC unit 15 performs the MVMs as multiply-accumulate (MAC) operations. The weights can be replaced by reprogramming the memory elements, as needed to perform the MVMs. As noted in the background section, using an IMC unit 15 is advantageous as it breaks the “memory wall” and addresses the Von-Neumann Bottleneck on the instruction interface, as discussed in the background section. Remarkably, a further acceleration is here achieved through the VPU 14. Indeed, the vector elements can be processed simultaneously across several processing elements, starting with processing elements of the IMC unit 15. They can further be processed by other components of the VPU, such as a vector execution unit, if necessary. Note, the vector elements can be repeatedly processed over several clock cycles; they can also be individually processed over successive clock cycles, as with scalar computing units.

As with conventional VPUs, the vector operations can be controlled by vector instructions, which can for instance be embedded into a regular instruction stream coming from a main processing unit (MPU) 12, as assumed in FIG. 1. The required vector instructions can for instance form an extension of a base Instruction Set Architecture (ISA), as in embodiments discussed later in detail. The MPU 12 is a neighbouring processor, or a set of processors, generally meant to execute non-vector instructions. The MPU is typically a scalar or superscalar processing unit. The MPU may for instance be a conventional processor, e.g., a central processing unit (CPU), or a customized processor, in which the VPU 14 is integrated, as in preferred embodiments.

In terms of architecture, the VPU 14 may comprise several subunits and components, including the IMC unit 15 itself. That is, the IMC may be integrated as a component of the VPU 14, which may itself be interfaced with or integrated in the MPU 12, as in preferred embodiments. Thus, the apparatus 10 shown in FIGS. 1 and 2B may possibly be manufactured as an integrated structure, e.g., a chip, integrating all components necessary to perform the computations. Such components may additionally include a memory 11, to which the MPU 12, the VPU 14, and the IMC unit 15 are connected, as assumed in FIGS. 1 and 2B. In variants, the components 11-15 are arranged as distinct components of a same device, or several connected devices, although a subset of these components may be co-integrated. Thus, the terminology “apparatus” used in respect of the present information-processing apparatuses 10 should be understood in a broad sense.

In the present context, the IMC unit 15 typically consumes one data vector and produces one output vector for each matrix-vector multiplication. Thanks to the connection between the IMC unit 15 and the VPU registers 148, the input vectors may transit from the memory 11 to the IMC unit 15, through the vector registers 148. The output vectors can be written in the vector registers 148 too (possibly in place of input vectors previously fed to the IMC unit 15), prior to transiting to another component 11, 12. I.e., eventually, the output vector components can be forwarded to the neighbouring memory 11 or the MPU 12 for further processing, this depending on the intended application. Such operations may require a careful orchestration, as described below in detail. The degree of orchestration required actually depends on the memory capacity of the registers 148. A small register capacity requires frequent replacement of the same registers. Alternatively, the output vectors may not necessarily need to overwrite the input vectors; they may rather be written in additional vector registers, the memory capacity of the vector registers permitting.

### 1.1.2. Advantages of the Proposed Solution

According to the proposed solution, the vector registers 148 of the VPU 14 are used both as source and destination buffers, whereby vector components can efficiently be injected to and received from the IMC unit. That is, the pipeline parallelism enabled by the vector registers makes it possible to operate the IMC unit 15 more efficiently for it to perform MVMs, let alone the MVM acceleration that is inherently achieved through the IMC unit 15 itself. Besides, one may take advantage of the vector processing capability of the VPU 12 to efficiently perform operations on the vector components that are temporarily stored in the registers, as in embodiments.

### 1.1.3. Preferred Embodiments

### 1.1.3.1 IMC Weights Storage and Updates

To start with, the information-processing apparatus 10 may be configured to perform weight transit operations and weight feed operations, which may advantageously exploit the vector registers 148, like the vector-related operations described above. That is, the weight transit operations aim at storing weights in the vector registers 148 first, while the weight feed operations are performed to feed the weights as stored in the vector registers to the IMC unit 15. The aim is to eventually store the weights across the crossbar array structure of the IMC unit 15, as necessary to subsequently perform MVMs. The memory capacity of the vector registers and/or throughput capabilities of the vector registers determine how such transit operations are performed. Both factors (i.e., memory capacity and throughput capabilities) may potentially be limiting factors, depending on the size of the crossbar array structure and the frequency at which the weights need to be replaced. If necessary, the weight-related operations are performed step wise, i.e., in stages, within limits imposed by the above factors.

In some cases, the weights may be stored in a single cycle if the vector register capacity permits. Else, the weight operations are performed step wise. For example, the weights can be fed to the IMC unit column by column or row by row and, if necessary, one portion after the other, where the maximal portion size is determined by the number of vector registers 148. The same mechanism can be used to initially store the weights and then update them, as needed to continually perform MVMs. I.e., the IMC unit 15 may continually perform MVMs based on updated weights and input vector components as continually fed to the IMC unit 15.

In practice, the weight matrix does not require frequent updates, at least compared to input vectors. In some scenarios, there is little advantage to directly load a weight matrix from the

memory 11 into the matrix register of the IMC unit 15 compared to loading individual rows or columns (or portions thereof) into the vector registers 148 first. In such situations, the vector registers 148 can be leveraged to update the weights, which makes it possible to simplify the cell programming. In other cases, however, it is more efficient to directly load the weights from the memory 11. A unit of the VPU (e.g., unit 144 in FIG. 1) may be connected to programming means 158 (see FIG. 4) of the IMC unit 15 to pass the weight values. In variants, or in addition, a controller 149 of the IMC unit 15 can be directly connected to the memory 11, as suggested by the dashed arrow in FIG. 1, to pass the weight values to the programming means 158. The apparatus 10 may actually be designed to provide both options and allow to choose between a direct load of the weights and an indirect transfer through the vector registers. Whether to directly load weights from the memory 11 or not may thus be automatically chosen, at run time, in accordance with characteristics of computations to be performed. Which option to use may also be configured, e.g., by a client when starting a job execution.

In general, the vector registers 148 may advantageously be designed to store any number P of numerical values, where P≥2. Preferably though, the registers are dimensioned so that this number P is larger than or equal to the number of values N, M stored across one column or one row of the IMC unit 15. I.e., P≥Min (N, M). This way, the IMC unit 15 can be updated one column or one row (at least) at a time.

### 1.1.3.2. In-Memory Processing Based on Multiple Weight Sets

Preferred embodiments are now discussed in reference to FIGS. 2A-4 . Instead of storing a single set of N×M weights, the IMC unit 15 may advantageously be able to store several sets of N×M weights, to accelerate the weight matrix updates and facilitate very large MVM operations. This requires modifying the memory systems 157 of the cells 155. That is, the crossbar array structure includes N×M cells 155, which comprise respective memory systems 157. Now, each memory system 157 can be designed to store K weight values at a time, where K≥2, instead of a single value. Each memory system 157 typically includes several memory elements in that case, where each element is capable of storing one numerical value. In practice, K may for instance be equal to 4 (as assumed in FIGS. 3 and 4), 8, 16, or 32. Overall, the crossbar array structure 15 includes N×M memory systems, which are capable of storing K sets of N×M weights, i.e., K×N×M weights in total.

Note, the memory elements of each memory system may themselves decompose into several components, meant to store distinct bit values, possibly a sign. That said, each memory elements should be able to store one true weight value at a time, such that each memory system is able to store K true weight values at a time and the crossbar can store K sets of N×M weight values. I.e., such an approach must be distinguished from technologies aiming at, e.g., decomposing a single matrix into a positive part and a negative part. Note, the above concept of crossbar is actually agnostic to the technology used for the memory systems, in each cell. I.e., this concept does not primarily depend on a specific circuit implementation; the weights may possibly be stored using any suitable memory technology, such as static random-access memory (SRAM), latches, or digital flip-flops, as well as resistive random-access memory (RRAM) cells, amongst other examples. The aim of storing K sets of N×M weight values is to reduce idle times of the core compute device, i.e., the crossbar array structure, something that is achieved by switching between active weights locally to accordingly reduce the frequency of data exchanges with an external memory unit.

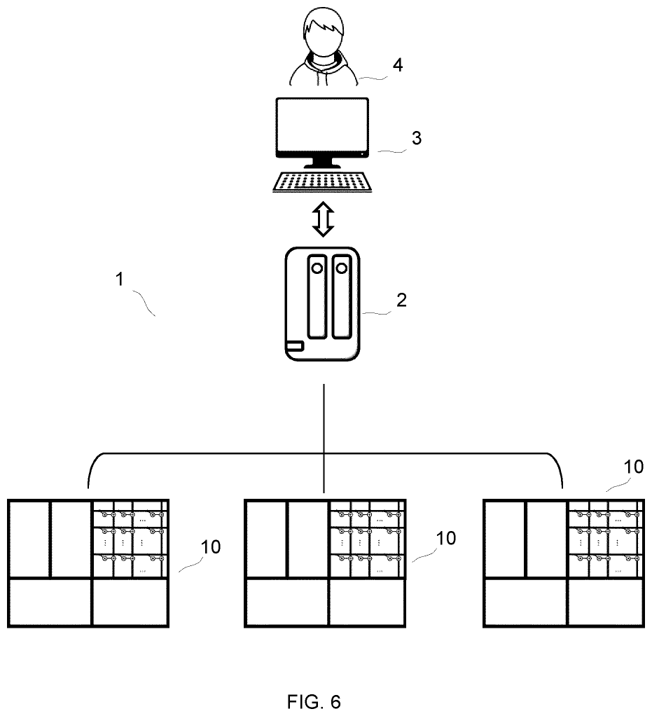

Thus, in embodiments, each cell involves a memory system 157 capable of storing K weights. Such weights are noted W_{ij,k} in FIG. 2A, where i runs from 1 to N,j from 1 to M, and k from 1 to K. This makes it possible to enable certain weights, prior to performing MAC operations based on given vectors and matrix coefficients corresponding to the enabled weights. A selection circuit 159 can be provided to select, for each memory system 157, a weight from its K weights and setting the selected weight as an active weight. This way, N×M weights can be enabled as active weights. Note, the selection and setting of the weights may actually be performed as a single operation, notably when using a selection circuit relying on multiplexers 159 connected to respective memory systems, as in embodiments discussed below in reference to FIGS. 4 and 5. What is more, such embodiments allow an entire matrix of N×M weights to be selected at a time.

Once a set of weights has been enabled, vector components can be fed to the crossbar array structure 15 via the vector registers. This way, an input vector of N components (also referred to as an “N-vector” herein) can be injected (as signals) to the N input lines 152 of the crossbar 15, for it to perform MAC operations based on the N-vector and the N×M active weights that are currently enabled. The MAC operations result in that the vector components values fed into the N input lines are respectively multiplied by the currently active weight values. As per the crossbar configuration, M MAC operations are being performed in parallel at each calculation cycle. Note, the operations performed at every cell correspond in fact to two scalar operations, i.e., one multiplication and one addition. Thus, the M MAC operations imply N×M multiplications and N×M additions, meaning 2×N×M scalar operations in total.

Output signals obtained at the M output lines 153 are subsequently read out to obtain corresponding values, which are buffered in the vector registers 148. In practice, several calculation cycles can be successively performed based on multiple N-vectors and multiple weights matrices. The output values of the MAC operations may actually correspond to partial values (should very large operands be involved), which may possibly be accumulated at the IMC unit, in output of the M columns, or directly in the registers 148, as discussed later in detail.

As said, the apparatus 10 may be configured to perform weight transit operations through the vector registers 148. In variants, the IMC may be programmed by directly fetching the weights from the neighbouring memory 11. This variant is advantageous where large sets of weights need be stored in the IMC and continually updated, something that can be done as a background task, i.e., behind the scenes, without interfering with the transits of input vectors. Even more so, this makes it possible to smoothly prefetch weights for subsequent computation cycles, without impacting the vector transits and thus the core computations. That is, the apparatus 10 may further be configured to prefetch q sets of N×M weights to store the prefetched weights in the N×M memory systems 157, in place of q sets of N×M weights that are currently not enabled as active weights, where 1≤q≤K−1. I.e., the q sets of N×M weights that are prefetched and stored in the IMC unit correspond to weights that are no longer active.

The prefetching operations may be carried out in a proactive manner, while the IMC unit 15 performs MVMs based on the N×M weights that are currently active, which results in a further acceleration. That is, the apparatus may proactively fetch and store weights that are planned to be used in subsequent MVMs. As said, the weights can be directly prefetched from memory, in the background, so as to interfere as little as possible with the current MVM operations.

Remarkably, the above solution allows distinct sets of weights to be locally enabled, timely, at the crossbar array 15, which makes it possible to reduce the frequency of data exchanges with the memory 11. This, in turn, reduces idle times of the IMC unit 15. I.e., idle times resulting from intermediate weight updates are avoided, because up to K successive computation cycles can be performed without the need to transfer new sets of weights. Instead, the relevant weight sets are locally enabled as active weights, when needed. And that the weights can be proactively loaded (i.e., prefetched during the compute cycles) further reduces idle times of the crossbar structure 15.

### 1.1.3.3. Accumulation

As illustrated in FIGS. 3 and 4, a column of arithmetic units 156 can be arranged next to every column of cells 155 of the IMC unit 15. Such arithmetic units can multiply the weights with input vector values, hence creating partial products. All partial products are successively accumulated by the adder tree of the unit 156 to produce the outcome of a full dot-product.

Additional accumulations may be performed to accommodate matrix-vector multiplications of very large operands, i.e., operands that cannot be directly accommodated by the crossbar array. The K matrices of N×M elements afforded by the crossbar array may indeed be sometimes insufficient to accommodate the desired (sometimes very large) operands, as with complex machine learning tasks. For example, a matrix-matrix multiplication involving large operands (matrices) can still be handled by a smaller-size IMC array, by decomposing an input matrix into input vectors, which are themselves partitioned into sub-vectors, to which distinct block matrices are assigned for performing successive matrix-vector multiplications, by locally enabling respective matrix coefficient arrays and accumulating partial results, either directly in the vector registers or in the IMC unit. Each final vector is then transferred to the neighbouring memory 11.

The required accumulations are preferably performed directly in the vector registers 148, thanks to an accumulation circuit interfaced with the vector registers 148. The accumulation circuit preferably forms part of the unit 146, as discussed below. This accumulation circuit is configured to accumulate vector component values produced by columns of the IMC unit 15. Thanks to this accumulation circuit, the output vector components can be directly accumulated in the vector registers 148. So, there is no need to provide accumulation circuits in the IMC unit in that case, which provides more flexibility in the design of the IMC unit.

Note, such accumulation circuits may, in principle, be provided on the paths connecting the readout units of the IMC unit to the vector registers 148. Preferably though, the accumulation circuits form part of a vector execution unit 146 of the VPU 14. That is, such accumulation operations can advantageously be performed in parallel, at the level of, or close to, the vector registers 148, by leveraging the compute capability of the vector execution unit 146. The latter may for instance be a general-purpose, parallel processing unit, e.g., designed to perform various operations, such as scaling, offsetting, and permutation operations. So, the unit 146 may well be leveraged to perform the desired accumulations, hence saving accumulation circuitry at the IMC level.

For completeness, further accumulations may have to be performed at the IMC unit in bit-serial implementations, as discussed later.

### 1.1.3.4. Preferred Architectures of the IMC Unit

FIG. 4 shows a programming circuit 158, which is designed to be sufficiently independent of the compute circuit 15, so as to be able to proactively reprogram weights that are currently inactive, while the compute circuit is performing MAC operations based on the currently active weights. This independence makes it possible to proactively load those weights that will be needed for next cycles of operations. Prefetching operations may for instance be performed for several sets of weights at a time (q≥2). Various prefetching schemes can be contemplated.

The programming circuit 158 may for instance connect the memory unit 11 to cells of the IMC unit 15. For example, digital memory cells (i.e., cells comprising digital memory elements) can be connected to dedicated lines, e.g., embodying word lines and bit lines for write operations in SRAM memory devices. Note, contrary to what the depiction of FIG. 4 suggests, the selection circuit 159 may possibly re-use the word lines and bit lines for read operations. Thus, the selection circuit and the programming circuit may, actually, partly overlap.

In the examples of FIGS. 4 and 5, each of the N×M memory systems 157 is assumed to include K distinct memory elements. Each memory element is adapted to store a respective weight value. In that case, the selection circuit may include N×M multiplexers 159. Each multiplexer is connected to all memory elements of a respective memory system 157, as in FIG. 4. In addition, selection control lines are connected to each multiplexer, to allow any of the K weights of each memory system 157 to be selected and set as an active weight, in operation. Selection bits can be conveyed through control lines to select the active weight, as illustrated in FIG. 5.

In the example of FIG. 5, the multiplexer is a channel multiplexer using inverters and logic “NAND” gates to arrive at a common output X. I.e., the combinational logic circuit switches one of several input lines A, B, C, D to a single common output line X. The data lines A, B, C, D correspond to W_{1,1,0}, W_{1,1,1}, W_{1,1,2}, W_{1,1,3} in FIG. 2. The data select lines (carrying the binary input addresses) are defined by Add₀ and Add₁, respectively corresponding to least significant bits (LSB) and most significant bits (MSB). A single multiplexer 157 is shown in FIG. 4, for simplicity. However, N×M multiplexers are used to switch the weights of the N×M memory systems. In principle, there are at most 2×N×M control lines, i.e., two control lines per multiplexer 159, to allow individual control of each multiplexer. However, in practice, control lines can be shared across the multiplexers, possibly all multiplexers, especially where one wishes to simultaneously select weights sets. Thus, all control lines are preferably shared, which allows the same index k for every element in the M x N memory system to be simultaneously selected. In such cases, the number of control lines can be reduced to Log₂(K) lines.

Similarly, the programming circuit 158 may involve N×M demultiplexers, where the same control bit lines are used for the whole array 15. A single demultiplexer 158 is shown to be connected to a respective memory system 157 in FIG. 4, for simplicity. However, in practice, there are N×M demultiplexers 158 and N×M multiplexers 159 connected to respective memory systems 157. In variants, the programming circuit 158 and the selection circuit 159 may include other types of electronic components, where such components are arranged in each cell or, at least, connect to each cell, as necessary to program and select the memory values. In further variants, each memory system 157 is configured to store K distinct values at respective local addresses, instead of being composed of K distinct memory elements.

As noted earlier, the required weights are preferably enabled all at once. To that aim, the selection circuit 159 may advantageously be configured to select a subset (at least) of n×m weights from one of the K sets of N×M weights. This is most efficiently achieved by concomitantly selecting the k^{th} weight of the K weights of each memory system of a subset of n×m memory systems 157, where 2≤n≤N, 2≤m≤M, and 1≤k≤K. Enabling weights of an n×m subarray may be advantageous for those matrix-vector calculations where not all the N×M weights must be switched, which depends on how the problem is initially mapped onto the N×M cells 155. Note, switching operations may infrequently have to be performed for a single cell (i.e., n=1 and m=1). In practice, however, weight selections mostly come to be performed simultaneously for a large subset of the N×M memory systems (i.e., n>1 and m>1), or even all of the N×M memory systems, especially where large operands matrices are involved. In variants, though, the selection circuit 159 may systematically select a set of N×M weights from one of the K sets of N×M weights, by concomitantly selecting the kth weight of the K weights of each of the N×M memory systems, to systematically switch all memory systems 157 simultaneously. Thus, in general, the selection circuit 159 is configured to select a set of n×m weights and set the latter as active weights, for n×m memory systems of the array 15, where 1≤n≤N and 1≤m≤M.

### 1.1.3.5. Preferred Implementations of the Vector and Main Processing Units

The following discussed preferred implementations of the VPU 14. As noted earlier, the information-processing apparatus 10 will typically include a controller 149 to orchestrate operations involving the IMC unit 15. This controller 149 may possibly form part of the IMC unit, as assumed in FIG. 1. As further seen in FIG. 1, the VPU 14 may also include a vector instruction decoder 142, which is connected to the controller 149. In that case, the vector instruction decoder 142 can be configured to decode vector instructions and transmit the decoded vector instructions to the controller 149. The controller 149 can notably be used to orchestrate the vector feed operations, the MVMs, and the vector readout operations. This is achieved thanks to the decoded vector instructions transmitted from the vector instruction decoder 142. Still, not all the vector instructions will be transmitted to the IMC controller 149, in practice. I.e., vector instructions could be transmitted to other units of the VPU 14, as discussed later. The controller 149 may similarly orchestrate weight feed operations, if necessary, based on decoded instructions transmitted by the vector instruction decoder 142.

Vector instructions control the IMC operations and are used to correctly synchronize the IMC operations, if only to make sure that output vectors are timely written to the vector registers 148, where the register size requires it. E.g., an output vector may only be written to the vector registers 148 once it is confirmed that the IMC unit 15 has duly completed the corresponding MVM and the previous output vector was duly transferred back to the memory 11 or the main processor 12. That is, a vector register should not be overwritten by the IMC output unless its content is no longer needed. That said, such synchronization constraints depend on the vector register size. Besides, another aspect of synchronization is that the IMC cannot begin a compute cycle until the intended input vector is indeed available in the vector registers.

Where the controller 149 has direct access to the memory 11 (see the dashed arrow in FIG. 1), then the controller 149 may also receive instructions to directly fetch the weights (but not the vector components) from the memory 11. In variants, the weights transit through the vector registers 148, as explained earlier. In both cases, though, the corresponding operations can be controlled thanks to vector instructions. Such vector instructions preferably form part of a vector instruction set designed in accordance with a base instruction set architecture.

Interestingly, the latter can be augmented with two types of vector instructions, which are designed to respectively cause to store the weights and perform the MVMs. That is, the operation of the IMC unit 15 can advantageously be controlled by extending an existing, standardized vector Instruction Set Architecture (ISA) with two new instructions. The first additional instruction aims at loading a data array into the IMC unit, while the second additional instruction is to perform the matrix-vector multiplication of an input vector with one of the IMC unit's internal matrices.

The following illustrates possible assembly formats for these instructions. First, the instruction for storing a vector into a row of the weight matrix may generally write as “vmvmtx md. r, vs”, where the instruction “vmvmtx” moves the source vector vs from the vector register file into row r of the IMC unit's internal destination matrix md. For example, the instruction “vmvmtx m0.3, v4” causes to move the source vector register v4 into row 3 of the internal matrix m0. Similarly, an instruction for multiplying a matrix by a vector can be written “vmulmtx vd, ms, vs”, which multiplies the source vector vs from the vector register file by the internal matrix ms and writes the result into the destination vector vd of the vector register file. For example, “vmulmtx v7, m2, v1” causes to multiply the source vector register v1 by the internal matrix m2 and write the resulting vector to the destination vector register v7.

Note, the above example of format of assembly instructions is consistent with the format used in the RISC-V ISA. That is, the above instructions can be regarded as a possible extension of the RISC-V ISA. Several variants can be contemplated. For example, the first additional instruction can be modified to further specify whether to directly load from memory (this can be performed by the vector load and store unit 144 or an additional, dedicated unit) or from the vector registers, depending on the chosen data transmission scheme. Thus, the first additional instruction may specify different memory/register addresses.

In the example of FIG. 1, the MPU 12 forms part of the apparatus 10. The MPU 12 is interfaced with the VPU 14 to forward vector instructions to the vector instruction decoder 142. That said, other architectures can be contemplated. Moreover, the memory 11 too forms part of the apparatus 10 in this example. In operation, this memory 11 serves as a main memory for the MPU 12. The memory 11 is interfaced with each of the MPU 12 and the VPU 14. The MPU 12 further comprises an instruction decoder 122, which is configured to fetch instructions from the memory 11, decode the fetched instructions, and accordingly forward the vector instructions to the VPU 14.

The VPU 14 may notably include a unit 144, called “vector load and store unit” in FIG. 1, which is configured to perform the vector transit operations, the weight transit operations (if necessary), and the vector readout operations, by transferring the corresponding values between the memory 11 and the vector registers 148. In operation, the instruction decoder 122 decodes instructions from the memory 11 to identify the types of instructions and which unit 12, 14 is responsible for executing them, hence the distinction between the conventional data path through the execution unit 126 and the vector data path through the VPU 14.

In addition, the MPU 12 typically includes registers 128 (storing respective values), a load and store unit 124 (to transfer data between the memory 11 and the registers 128), and an arithmetic and logic unit 126. The unit 126 is a processing element that reads values from the source registers, performs operations on such values, and stores the result back into the destination registers of the registers 128.

For completeness, the VPU 14 may also comprise a vector execution unit 146, as noted earlier. The latter may notably read vector data from the vector registers 148 and perform operations on the corresponding vectors, e.g., element-wise operations on individual vector components, reduction operations, or permutations of the individual vector components, if necessary. In addition, the vector execution unit 146 stores output vectors into vector registers 148 and, if necessary, accumulates partial values, as discussed earlier. Note, in practice, the vector instructions will typically distinguish between the source vector registers and the destination vector registers of the registers 148. However, both types of instructions concern the same physical registers.

### 1.2. Information-Processing Systems

The present invention may further be embodied as an information-processing system 1, such as depicted in FIG. 6. In this example, the system 1 is a network of interconnected machines, which includes three apparatuses 10 as described above. More generally, though, the system 1 may comprise any number of such apparatuses 10. The latter may notably be connected to a server 2, as further assumed in FIG. 6. As a whole, the system 1 allows a user to interact with the server 2, in order to accelerate machine learning computation tasks or other tasks involving MVMs, which are offloaded to the apparatuses 10, as in embodiments. That is, the server 2 interacts with clients 4, who may be natural persons (interacting via personal computers 3), processes, or machines. Each apparatus 10 is configured to read data from, and write data to, a memory unit of the server 2 in this example. Client requests are managed by the server 2, which may for instance be configured to map a given computing task onto vectors and weights, which are then passed to the apparatuses 10 for efficiently performing MVMs.

The system 1 may also be configured as a composable disaggregated infrastructure, which may further include other hardware acceleration devices, e.g., application-specific integrated circuits (ASICs) and/or field-programmable gate arrays (FPGAs). More generally, other architectures can be contemplated. For example, the system 1 may be configured as a standalone system, possibly connected to one or more general-purpose computers. The system 1 may notably be used in a distributed computing system, such as an edge computing system.

### 1.3. Methods of Operating IMC Units Using Vector Processing

### 1.3.1. Main Features and Variants

A final aspect of the invention is now described in reference to FIG. 7. This aspect concerns a method of operating an IMC unit 15 to perform MVMs. As explained earlier in reference to the first aspect of the invention, the IMC unit 15 has a crossbar array structure, which can store matrix weights, and is connected to vector registers 148 of a VPU 14. The method essentially revolves around performing vector transit operations, vector feed operations, MVMs, and vector readout operations, as discussed earlier in reference to the first aspect.

A vector transit operation causes to store input vector components of an input vector in the vector registers 148, see step S144 in FIG. 7. Next, a vector feed operation is performed to feed S145 the input vector components as input to the IMC unit 15, from the vector registers. The IMC unit 15 is then operated to perform S146 an MVM based on the weights stored across the cells 155 of the crossbar array structure and the input vector components fed to the IMC unit 15. This causes to form an output vector. Finally, a vector readout operation is performed to write S147 output vector components of the output vector in the vector registers 148. From this point on, a new cycle can be performed, based on new input vector components.

Vector components can for instance be fetched from a neighbouring memory 11 (interfaced with the VPU 14) and possibly transit through the vector registers 148, as discussed earlier. Conversely, the output vector components can eventually be transferred S148 from the vector registers 148 to the memory 11 or a connected MPU 12, after performing S147 a vector readout operation.

Weights are stored in the IMC unit 15 prior to starting any MVM operation. As said, such weights may also need to be updated. To that aim, the weights can be fetched (possibly proactively) from the memory 11 and then be directly loaded in the IMC unit 15. Alternatively, the weights may transit though the vector registers 148. In that case, the method performs weight transit operations to store S141 the weights in the vector registers 148 and then weight feed operations to feed S142 the weights to the IMC unit 15, so as to store the weights across cells 155 of the crossbar array structure. The weight transit operations and the weight feed operations may have to be performed step wise, this depending with a memory capacity of the vector registers 148.

The crossbar array structure includes N×M cells 155, which comprise respective memory systems 157. As explained in Sect. 1.1.3.2., the latter may advantageously be designed to store K weights (K≥2), such that the N×M memory systems may store K sets of N×M weights. In that case, N×M weights must be as enabled S149 as active weights prior to performing S146 any MVM. This is achieved by selecting, for each memory system 157, a weight from its K weights and setting the selected weight as an active weight. As explained earlier too, this makes it possible to proactively prefetch weights, while the IMC unit 15 performs MVMs based on the currently active weights. I.e., q sets of N×M weights may be prefetched S141, so as to store the prefetched weights in the N×M memory systems 157, in place of q sets of N×M weights that are currently not enabled as active weights, where 1≤q≤K−1.

The various operations can be orchestrated thanks to suitably designed vector instructions, e.g., sent S126 from an MPU 12 interfaced with the VPU 14. Next, the VPU 14 may decode the vector instructions and execute the decoded instructions to orchestrate all required operations, starting with the vector transit operations, the vector feed operations, and the vector readout operations, as well as weight-related operations if necessary. The vector instructions may advantageously form part of a vector instruction set designed in accordance with a basis ISA, augmented with two types of vector instructions, the latter designed to cause to respectively cause to store the weights and perform the MVMs.

The above embodiments have been succinctly described in reference to the accompanying drawings and may accommodate a number of variants. Several combinations of the above features may be contemplated. Examples are given in the next section.

### 1.3.2. Preferred Flow of Operations

FIG. 7 shows a preferred flow of operations. Essentially, the MPU 14 (e.g., a main core) interacts with the memory 11 to load S122 instructions and decode S124 such instructions.

Some of these instructions are processed internally by the MPU, while other instructions are forwarded S126 to the VPU 12 (called vector core in FIG. 7), for it to transfer weights and input vectors to the IMC unit 15, with a view to performing MVMs.

Upon receiving such instructions, the VPU 14 may dispatch instructions to the controller 149 for it to fetch (or prefetch) S141 weight data from the memory 11 and then write S142 the weight data across the cells 155 of the IMC unit 15. In variants, the VPU may first store the weight data in the vector registers, prior to injecting S142 the weight data to the IMC unit from the vector registers. The loading of the weight data may have to be performed step wise (S142a: No). An MVM cycle can start once all the weights necessary for starting this cycle have been stored in the IMC unit (S142a: Yes). The prefetching (S141, S142) of weight data can already start once an MVM cycle has completed (assumed the corresponding weight matrix is no longer needed). The prefetching mechanism is continually implemented, i.e., behind the scenes, while the IMC unit 15 performs MVMs.

A given set of weights is enabled S149, prior to starting MVMs. To that aim, a next input vector is selected S143, and components of this vector are stored S144 in the vector registers and then passed to the IMC unit, for it to perform S146 an MVM based on this input vector and the weights as currently enabled as active weights. The resulting output vector is written S147 to the vector registers. The outcome of the successive MVM operations is monitored (S147a: Yes, No). Once a current MVM has completed (S147a: yes), the output vector is transferred S148 to the memory 11. The transfer is monitored (S148a), to make sure not to overwrite an output vector. Once it is confirmed that the transfer has completed (S148a: Yes), a process checks whether all input vectors have been processed (i.e., in respect of the current weight matrix). If not (S148b: No), then a next input vector is selected S143, with a view to performing a new MVM operation.

Note, the flow of FIG. 7 makes sure that no new vector components can enter S144 the vector registers before the output vector from the previous MVM operation has been transferred (S148a: Yes) to the memory 11. Once all input vectors have been processed for the current weight matrix (S148b: Yes), a new set of weight is enabled S149, to start new MVM calculation cycles. If necessary, further weights can be proactively fetched S142, S142 while the MVMs execute. Note, the output vectors may possibly be accumulated in the vector registers, if necessary to accommodate large operands, as discussed earlier. In that case, only the final output vector is transferred to the memory 11.

### 2. Particularly Preferred Embodiments and Technical Implementation Details

### 2.1. Preferred Architecture of the Apparatus

As illustrated in FIG. 1, the apparatus 10 preferably includes a memory 11, an MPU 12, and a VPU 14, where the latter includes the IMC unit 15, which is integrated in the VPU 12. The VPU is co-integrated with the memory 11 and the MPU 15 on a same chip. I.e., the apparatus 10 is a single device of integrated components 11, 12, 14 (and 15).

The MPU 12 (“main core” in FIG. 1) includes an instruction decoder 122, which is connected to the memory 11 to obtain instructions that it decodes and forwards to the load and store unit 124 or the execution unit 126. The load and store unit 124 exchanges data with the memory 11, in accordance with instructions received from the execution unit 126 of the MPU or the VPU 12. Each of the load and store unit 124 and the execution unit 126 can write to and read from the register file 128.

The VPU 14 (“vector core”) includes a vector instruction decoder 142, serving as an interface with the MPU 12. The vector instruction decoder 142 gets instructions from the instruction decoder 122, decodes such instructions and forwards them to the relevant entities 144, 146, 149 of the VPU 14. In particular, the vector instruction decoder 142 communicates with the vector load and store unit 144 for it to read input vectors from the memory 11 and write output vectors back to the memory 11. The vector instruction decoder 142 further communicates with the vector execution unit 146 for it to perform any required operation (e.g., accumulations, permutations, scaling operations, offset operations, etc.) on the vector stored in the vector registers, if necessary. Finally, the vector instruction decoder 142 communicates with the controller 149 of the IMC unit 15, to suitably orchestrate all operations related to the MVMs (i.e., fetching weight data, loading input vectors from the vector registers 148, performing the MVMs, and writing output vectors to the vector registers 148). Note, the controller 149 may directly fetch weight data from the memory, as suggested by the dashed arrow, upon being instructed to do so by the vector instruction decoder 142.

### 2.2. Preferred Architecture of the Crossbar Array Structure

The crossbar array structure 15 includes N input lines 152 and M output lines 153. The input lines and output lines 152, 153 are interconnected at cross-points (i.e., junctions), which define N×M cells 155. Each cell 155 includes a respective memory system 157. Each of the N×M memory systems includes K memory elements, each adapted to store a respective weight of the K weights. Thus, each memory system 157 can store up to K weights, where K is equal to 4. Overall, the crossbar array structure 15 can store K×N×M weights in total. The input lines 152 and output lines 153 form an array of 512 x 512. Other crossbar array dimensions can be contemplated, as exemplified in Sect. 1.

The IMC unit may further comprise an input unit (not shown) to apply input signals to the N input lines 152, a programming circuit 158, a selection circuit 159, and a readout unit (not shown), which may include accumulators, unless accumulations are performed directly in the vector registers. The selection circuit 159 and the input unit may for instance form part of a same configuration and control logic circuit and be controlled by a same logic unit, connected to, or forming part of, the controller 149.

The memory elements are preferably digital memory elements, such as SRAM devices. More generally, the present IMC units are compatible with various types of electronic memory devices, including non-volatile memory elements (e.g., flash cells). Any type of memristive devices can for instance be contemplated, such as phase-change memory cells, RRAM elements, and electro-chemical random-access memory (ECRAM) devices. In other variants, the memory elements are analogue memory elements. In that case, each multiply-accumulate operation, i.e., ΣᵢW_{i,j,k} xᵢ, is performed analogically and the output signals are translated to the digital domain using analogue-digital converter (ADC) circuitry.

For instance, each of the K memory elements is a digital memory element such as an SRAM device. In that case, each cells 155 includes an arithmetic unit 156 (including a multiplier and adder tree, see FIGS. 3 and 4), which is connected to each of the K memory elements of a respective memory system 157 via a respective selection circuit portion 159 (e.g., a multiplexer). Each cell is physically connected to each memory element via a selection circuit component (such as a multiplexer or any other selection circuit component) but is logically connected to only one such element at a time, by virtue of the selection made by the selection circuit.

In bit-serial implementations, each memory element is designed to store a P-bit weights. An input unit (not shown) is configured to apply input signals, to feed components of the N-vectors bit-serially to the input lines 152 in P cycles, where P≥1 or, more likely, P≥2, e.g., P=8 or 16). P corresponds to a bit width of each of the N components of each of the vectors used in input; each vector component corresponds to a P-bit input word. The N×M cells 155 must then be designed to perform MAC operations in a bit-serial manner (i.e., in P cycles). The hardware device 10 includes an accumulator circuit, e.g., in output of the columns to accumulate values corresponding to partial, bit-serial product values as obtained at each of the P cycles. Meanwhile, the selection circuit 159 maintains a same set of N×M weights as active weights during each of the P cycles.

Beyond bit-serial implementations, the present concepts can also be implemented using a parallel implementation, which, however, does not require any parallel-to-serial conversion. In parallel implementations, each N-vector is processed with weight multiplication in a single cycle. In further variants, hybrid approaches can be contemplated, involving parallel feed of bit-serial values.

While the present invention has been described with reference to a limited number of embodiments, variants, and the accompanying drawings, it will be understood by those skilled in the art that various changes may be made, and equivalents may be substituted without departing from the scope of the present invention. In particular, a feature (device-like or method-like) recited in a given embodiment, variant or shown in a drawing may be combined with or replace another feature in another embodiment, variant, or drawing, without departing from the scope of the present invention. Various combinations of the features described in respect of any of the above embodiments or variants may accordingly be contemplated, that remain within the scope of the appended claims. In addition, many minor modifications may be made to adapt a particular situation or material to the teachings of the present invention without departing from its scope. Therefore, it is intended that the present invention is not limited to the particular embodiments disclosed, but that the present invention will include all embodiments falling within the scope of the appended claims. In addition, many other variants than explicitly touched above can be contemplated. For example, other types of memory elements, selection circuits, and programming circuits can be contemplated.

1. An information-processing apparatus comprising:
a vector processing unit having vector registers designed to store vector components; and
an in-memory compute unit, or IMC unit, having a crossbar array structure connected to the vector registers and adapted to store weights, wherein the information-processing apparatus is configured to perform:
vector transit operations to store input vector components of input vectors in the vector registers;
vector feed operations to feed said input vector components as input to the IMC unit, from the vector registers, for the IMC unit to perform matrix-vector multiplications, or MVMs, based on the weights and the input vector components, to obtain output vectors, and
vector readout operations to write output vector components of the output vectors in the vector registers.

2. The information-processing apparatus according to claim 1, wherein the information-processing apparatus is further configured to perform:
weight transit operations to store the weights in the vector registers; and
weight feed operations to feed the weights to the IMC unit from the vector registers, so as to store the weights across the crossbar array structure.

3. The information-processing apparatus according to claim 1, wherein the crossbar array structure includes
N×M cells comprising respective memory systems, each designed to store K weights, K≥2, whereby the crossbar array structure includes N×M memory systems adapted to store K sets of N×M weights, and
a selection circuit configured to enable N & M weights as active weights by selecting, for each of the memory systems, a weight from its K weights and setting the selected weight as an active weight.

4. The information-processing apparatus according to claim 3, wherein the information-processing apparatus is further configured to
prefetch q sets of N×M weights, while the IMC unit performs MVMs based on the N×M weights that are currently active, so as to store the prefetched weights in the N×M memory systems, in place of q sets of N×M weights that are currently not enabled as active weights, where 1≤q≤K−1.

5. The information-processing apparatus according to claim 4, wherein the selection circuit includes
N×M multiplexers, each connected to each of the K memory elements of a respective one of the N×M memory systems, as well as
selection control lines, which are connected to each of the multiplexers, to allow any one of the K weights of each of the memory systems to be selected and set as an active weight, in operation.

6. The information-processing apparatus according to claim 1, wherein
the information-processing apparatus further comprises an accumulation circuit interfaced with the vector registers, and
the accumulation circuit is configured to accumulate output vector components of output vectors obtained from the IMC unit, in operation.

7. The information-processing apparatus according to claim 1, wherein
the vector registers are designed to store a given number of numerical values, wherein said given number is larger than or equal to a smallest value of Wand M.

8. The information-processing apparatus according to claim 1, wherein
the information-processing apparatus further includes a controller, which preferably forms part of the IMC unit,
the vector processing unit includes a vector instruction decoder connected to said controller (149),
the vector instruction decoder is configured to decode vector instructions and transmit the decoded vector instructions to the controller, and
the controller is configured to orchestrate the vector feed operations, the MVMs, and the vector readout operations, based on the decoded vector instructions transmitted from the vector instruction decoder.

9. The information-processing apparatus according to claim 1, wherein
the information-processing apparatus is further configured to store the weights across the crossbar array structure,
said vector instructions form part of a vector instruction set designed in accordance with a base instruction set architecture augmented with two types of vector instructions, and
the two types of vector instructions are designed to respectively cause to store the weights and perform the MVMs.

10. The information-processing apparatus according to claim 8, wherein the information-processing apparatus further comprises:
a main processing unit configured to execute non-vector instructions, wherein the main processing unit is interfaced with the vector processing unit to forward the vector instructions to the vector instruction decoder.

11. The information-processing apparatus according to claim 10, wherein
the information-processing apparatus further comprises a memory interfaced with each of the main processing unit and the vector processing unit,
the main processing unit further comprises an instruction decoder configured to fetch instructions from the memory, decode the fetched instructions, and accordingly forward the vector instructions to the vector processing unit, and
the vector processing unit further comprises a vector load and store unit configured to perform the vector transit operations and the vector readout operations, by transferring corresponding values between the memory and the vector registers.

12. The information-processing apparatus according to claim 1, wherein the IMC unit is integrated in the vector processing unit.

13. An information-processing system comprising one or more information-processing apparatuses according to claim 1.

14. A method of operating an in-memory compute unit, or IMC unit, to perform matrix-vector multiplications, or MVMs, wherein the IMC unit has a crossbar array structure storing weights and is connected to vector registers of a vector processing unit, and wherein the method comprises:
performing a vector transit operation to store input vector components of an input vector in the vector registers;
performing a vector feed operation to feed said input vector components as input to the IMC unit, from the vector registers,
operating the IMC unit to perform a matrix-vector multiplication, or MVM, based on the weights stored and the input vector components fed to the IMC unit, to obtain an output vector, and
performing a vector readout operation to write output vector components of the output vector in the vector registers.

15. The method according to claim 14, wherein the method further comprises, prior to performing the vector transit operation and the vector feed operation, performing:
weight transit operations to store the weights in the vector registers; and
weight feed operations to feed the weights to the IMC unit, so as to store the weights across the crossbar array structure.

16. The method according to claim 14, wherein
the crossbar array structure includes N×M cells (155) comprising respective memory systems, each designed to store K weights, K≥2, whereby the crossbar array structure includes N×M memory systems adapted to store K sets of N×M weights, and
the method further comprises, prior to performing said MVM, enabling said N×M weights as active weights by selecting, for each of the memory systems, a weight from its K weights and setting the selected weight as an active weight.

17. The method according to claim 16, wherein the method further comprises,
while the IMC unit performs MVMs based on the currently active weights, prefetching q sets of N×M weights to store the prefetched weights in the N×M memory systems, in place of q sets of N×M weights that are currently not enabled as active weights, where 1≤q≤K−1.

18. The method according to claim 14, wherein the method further comprises,
at the vector processing unit, decoding vector instructions and executing the decoded instructions to orchestrate the weight transit operations, the weight feed operations, the vector transit operations, the vector feed operations, and the vector readout operations.

19. The method according to claim 18, wherein
the vector instructions form part of a vector instruction set designed in accordance with a basis instruction set architecture augmented with two types of vector instructions, the latter designed to cause to respectively cause to perform said weight feed operations and said MVMs.

20. The method according to claim 19, wherein
the method further comprises, prior to decoding the vector instructions at the vector processing unit, sending the vector instructions from a main processing unit interfaced with the vector processing unit.

21. The method according to claim 16, wherein the method further comprises:
fetching the input vector components from a memory interfaced with the vector processing unit, prior to performing the vector transit operation to store the input vector components of this input vector in the vector registers; and
transferring the output vector components from the vector registers to the memory, after performing said vector readout operation.
